(19) United States
(12) Patent Application Publication
(10) Pub. No.: US 2023/0361094 A1
(43) Pub. Date: Nov. 9, 2023

(54) SUBSTRATES FOR MICROLED AND MICRO-ELECTRONICS TRANSFER

(71) Applicant: CORNING INCORPORATED, Corning, NY (US)

(72) Inventors: Ya-Huei Chang, Hsinchu County (TW); Sean Matthew Garner, Elmira, NY (US); David Robert Heine, Seminole, FL (US)

(21) Appl. No.: 18/026,168

(22) PCT Filed: Nov. 17, 2021
(86) PCT No.: PCT/US2021/059623

§ 371 Date: Mar. 14, 2023

Related U.S. Application Data
(60) Provisional application No. 63/117,653, filed on Nov. 24, 2020.

(51) Int. Cl. H01L 25/16; C03C 17/06; H01L 27/12

(52) U.S. Cl. CPC H01L 25/167; C03C 17/06; H01L 27/1214

(57) ABSTRACT

A glass substrate with improved microLED transfer characteristics is disclosed, the glass substrate comprising a first major surface, a second major surface opposite the first major surface, and a thickness therebetween. An electrically functional layer may be disposed on the first major surface. The glass wafer exhibits a waviness with a magnitude less than or equal to about 1 μm in a spatial wavelength range from about 0.25 mm to about 50 mm.

### CROSS-REFERENCE TO RELATED APPLICATIONS

This application claims the benefit of priority under 35 U.S.C. § 119 of U.S. Provisional Application Ser. No. 63/117,653 filed on Nov. 24, 2020 the content of which is relied upon and incorporated herein by reference in its entirety.

### FIELD

The present disclosure relates generally to substrates for microLED and micro-electronics transfer, and, more particularly, to glass substrates exhibiting optimized geometrical attributes.

### BACKGROUND

Displays based on micro-light emitting diode (microLED) technology are poised to compete with current display technology over the next few years given some of their inherent benefits, such as improved resolution and contrast ratio compared to standard LED signage, better lifetimes, contrast ratio, and larger seamless tiled displays than organic light emitting diode display (OLEDs). An impediment to large scale manufacture of microLED displays is the need to transfer millions of microLEDs onto each display substrate with near-perfect success. Transferred microLED yields of 99.9999% are targeted, yet the current industry level is approximately 99.9%. Presently, transfer technology involves a mechanical, electrostatic, or magnetic stamp transfer technique where a set of microLEDs is transferred from a source wafer onto a stamp, and then from the stamp onto a receiving substrate, typically made of glass. Successful transfer requires well-formed and accurately aligned microLEDs on the stamp surface, accurate positioning and contact of the stamp with the substrate, and a substrate with well-controlled bulk and surface properties to receive the microLEDs.

### SUMMARY

Substrates considered for microLED transfer originate from a couple different regimes. In one case, substrates are considered for use as an intermediate (temporary) transfer carrier. The substrates are typically characterized in terms of their composition and overall shape, and the quality of a substrate is assessed by a total thickness variation (TTV), warp (or bow), and roughness. In another case, large Gen-size glass sheets can be used for display backplane applications. Example specified attributes include full-sheet warp, waviness (in specified spatial wavelength ranges)), and moving window thickness variation. Although these attributes are meaningful fur photolithography-based backplane fabrication and temporary or permanent bonding between silicon-glass or glass-glass backplanes, they do not specify sufficient criteria for successful microLED transfer assembly. For these new microLED applications, substrates that use the previous guidelines for TTV, warp, and roughness are assumed to result in fewer defects when transferring microLEDs to the substrate surface. However, this guidance can do a poor job of predicting the transfer success of microLEDs onto the substrate surface. Stronger predictors of microLED transfer efficiency are new target ranges for waviness.

Substrates with at least low waviness are better substrates for receiving microLEDs in stamp transfer processes, for example with improved transfer efficiency compared to substrates with low TTV or warp alone. Spatial wavelength ranges are identified where the transfer process is particularly sensitive to waviness. Substrates that show low waviness in these ranges of spatial wavelengths can perform significantly better than existing products.

By identifying substrate features determinate of microLED stamp transfer efficiency, a substantial quality improvement can be made over prior technology. Whereas substrate suppliers measure, and manufacturers specify, warp and TTV as quality metrics, using waviness as a further quality metric can yield better-performing substrates. For future applications, as manufacturers move to larger stamp sizes, the specific spatial wavelength range of features that should be minimized to produce acceptable transfer efficiency are identified.

Accordingly, a substrate is disclosed comprising a first major surface, a second major surface opposite the first major surface, and a thickness therebetween, the substrate further comprising a maximum waviness over a 50 mm×50 mm area of the first or second major surface, for example over a 40 mm×40 mm area, such as over a 30 mm×300 mm area, or a 20 mm×20 mm area, with a magnitude less than or equal to about 1 μm, for example equal to or less than about 0.5 μm, in a spatial wavelength range from about 0.25 mm to about 50 mm, for example in a spatial wavelength range from about 20 mm to about 50 mm, such as in a spatial wavelength range from about 30 mm to about 50 mm.

In some embodiments, the substrate may further comprise an electrically functional layer disposed thereon, for example on the first major surface and/or the second major surface. The electrically functional layer can comprises a plurality of metallic conductors. In some embodiments, the electrically functional layer can comprise a thin film transistor (TFT).

The substrate may further comprise an adhesive layer disposed over the substrate, for example on at least one of the first or second major surface.

In some embodiments, a surface area of the first and/or second major surface can be equal to or greater than about 1×10⁴ mm². In some embodiments, the surface area of the first and/or second major surface can be equal to or greater than about 1 m². A thickness of the substrate between the first major surface and the second major surface can be in a range from about 0.1 mm to about 1 mm.

The substrate may be a glass substrate, for example a silica-based glass substrate (e.g., equal to or greater than about 50% by weight silica), although in further embodiments, the substrate may be a silicon substrate (e.g., a silicon wafer).

In various embodiments, a coefficient of thermal expansion (CTE) of the substrate can be in a range from about 3 ppm/° C. to about 10 ppm/° C. over a temperature range from about 0° C. to about 300° C. when measured according to ASTM C1350M-96 (2019).

Additional features and advantages of the embodiments disclosed herein will be set forth in the detailed description that follows, and in part will be clear to those skilled in the art from that description or recognized by practicing the embodiments described herein, including the detailed description which follows, the claims, as well as the appended drawings.

It is to be understood that both the foregoing general description and the following detailed description present embodiments intended to provide an overview or framework for understanding the nature and character of the embodiments disclosed herein. The accompanying drawings are included to provide further understanding and are incorporated into and constitute a part of this specification. The drawings illustrate various embodiments of the disclosure, and together with the description explain the principles and operations thereof.

### BRIEF DESCRIPTION OF THE DRAWINGS

FIG. 1 is a cross-sectional drawing of a substrate illustrating total thickness variation (TTV);

FIG. 2 is a cross-sectional view of a substrate illustrating warp;

FIG. 3 is a series of illustrations demonstrating waviness;

FIG. 4 is a cross-sectional view of a stamp with a plurality of electronic devices, e.g., microLEDs, disposed thereon and positioned over a substrate comprising a non-planar surface topography;

FIG. 5 is a cross-sectional view of the stamp of FIG. 5 as the stamp approaches the substrate, and illustrates incomplete transfer of the electronic devices to the substrate;

FIG. 6 is a scatter plot showing the results of simulated electronic device transfer efficiency as a function of substrate waviness for various glass substrate samples;

FIG. 7 is a scatter plot showing the results of simulated electronic transfer efficiency as a function of substrate TTV for various glass substrate samples;

FIG. 8 is a scatter plot showing the results of simulated electronic device transfer efficiency as a function of substrate warp for various glass substrate samples; and

FIG. 9 is a graph showing simulated electronic device transfer efficiency as a function of stamp size.

### DETAILED DESCRIPTION

Reference will now be made in detail to embodiments of the present disclosure, examples of which are illustrated in the accompanying drawings. Whenever possible, the same reference numerals will be used throughout the drawings to refer to the same or like parts. However, this disclosure can be embodied in many different forms and should not be construed as limited to the embodiments set forth herein.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Ranges can be expressed herein as from “about” one particular value, and/or to “about” another particular value. When such a range is expressed, another embodiment includes from the one particular value to the other particular value. Similarly, when values are expressed as approximations by use of the antecedent “about,” it will be understood that the particular value forms another embodiment. It will be further understood that the endpoints of each of the ranges are significant both in relation to the other endpoint, and independently of the other endpoint.

Directional terms as used herein—for example up, down, right, left, front, back, top, bottom—are made with reference to the figures as drawn and are not intended to imply absolute orientation.

Unless otherwise expressly stated, it is in no way intended that any method set forth herein be construed as requiring that its steps be performed in a specific order, nor that with any apparatus, specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred in any respect. This holds for any possible non-express basis for interpretation, including matters of logic with respect to arrangement of steps, operational flow, order of components, or orientation of components; plain meaning derived from grammatical organization or punctuation, and; the number or type of embodiments described in the specification.

As used herein, the singular forms “a,” “an” and “the” include plural references unless the context clearly dictates otherwise. Thus, for example, reference to “a” component includes aspects having two or more such components, unless the context clearly indicates otherwise.

The word “exemplary,” “example,” or various forms thereof are used herein to mean serving as an example, instance, or illustration. Any aspect or design described herein as “exemplary” or as an “example” should not be construed as preferred or advantageous over other aspects or designs. Furthermore, examples are provided solely for purposes of clarity and understanding and are not meant to limit or restrict the disclosed subject matter or relevant portions of this disclosure in any manner. It can be appreciated that a myriad of additional or alternate examples of varying scope could have been presented but have been omitted for purposes of brevity.

As used herein, the terms “comprising” and “including”, and variations thereof, shall be construed as synonymous and open-ended, unless otherwise indicated. A list of elements following the transitional phrases comprising or including is a non-exclusive list, such that elements in addition to those specifically recited in the list may also be present.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Unless otherwise indicated, drawings are not to scale.

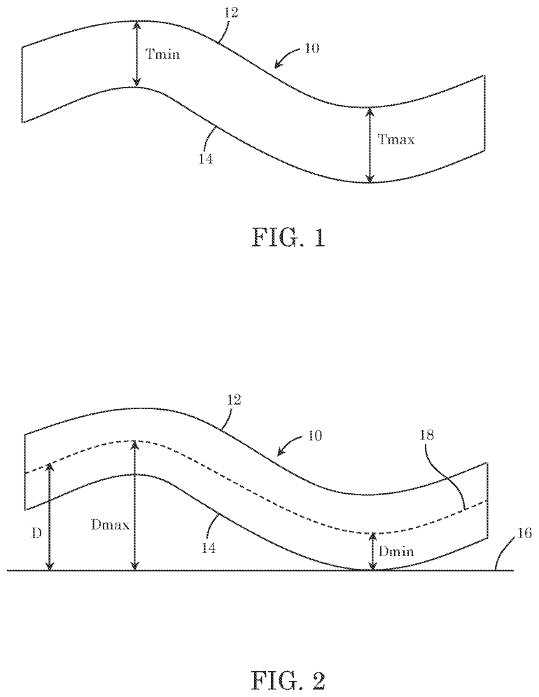

As shown in FIG. 1, total thickness variation (TTV) refers to the difference between a maximum thickness Tmax of a substrate 10 and the minimum thickness Tmin of the substrate 10, wherein the substrate 10 comprises a first major surface 12 and a second major surface 14 opposite first major surface 12. Thickness is defined as the distance between a first point on the first major surface and a second point on the second major surface, the first and second points lying on a line orthogonal to at least one of the first major surface or the second major surface. Accordingly, TTV depends on the topography of both the first major surface and the second major surface. TTV can be calculated as Tmax-Tmin. Whereas TTV is used in reference to an entire substrate, a local thickness variation (LTV) can be defined as the thickness variation of a portion of the substrate. Thus, LTV may be used to refer to the thickness variation over a surface area less than the total area of a particular substrate, for example and area approximately the size of a stamp used to transfer microLEDs to the substrate.

Referring to FIG. 2, warp is a measure of the variation in distance D between a reference surface 16 and a centerline 18 of the substrate 10. Warp can be calculated as (Dmax-Dmin)/2.

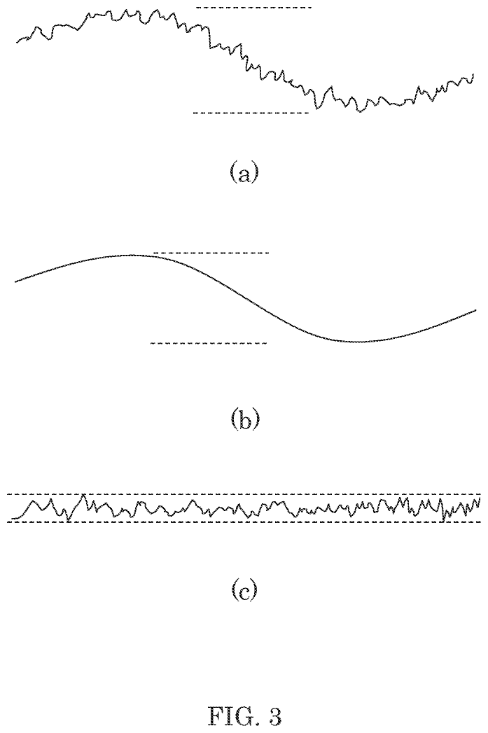

Waviness is a measure of a topography of a major surface of the substrate after removing surface features with spatial wavelengths greater than, e.g., 50 millimeters (mm) and smaller than 0.25 mm. For example, as illustrated in FIG. 3(a)-3(c), raw surface topography data (FIG. 3a) can be filtered with a Gaussian filter (FIG. 3(b)) to remove large-scale surface features (e.g., features with a spatial frequency greater than about 50 mm), yielding surface waviness (FIG. 3(c)). Features with spatial frequencies less than about 0.25 mm can be characterized as surface roughness and similarly removed.

MicroLED transfer processes can include four different scenarios: 1) transfer from the native epitaxial substrate to an intermediate (temporary) substrate; 2) transfer from the native epitaxial substrate to a final backplane substrate; 3) transfer from an intermediate substrate to another intermediate substrate; and/or 4) transfer from an intermediate substrate to a final backplane substrate. In these four cases, the receiving substrate may be a bare substrate (e.g., bare, uncoated glass), a substrate coated with an adhesive, or a substrate with a fabricated electronic component, e.g., an electrically functional layer. As used herein, an electrically functional layer refers to a layer or layers on the substrate that conduct or otherwise utilize and/or transfer electrical energy between components utilized in an electrical device that comprises the substrate. For example, an electrically functional layer may comprise an electrically conductive metallic layer. Electrical conductors can include electrical traces used to deliver an electrical current and/or voltage to one or more electronic components. Electrical traces can be electrical power traces or electrical data lines. Electrical traces can be patterned on the substrate by conventional means, such as photolithography. An electrically functional layer may further include electronic components such as thin film transistors (TFTs) or other electronic and/or electrical components, including without limitation resistors, capacitors, inductors, transistors, diodes, including light emitting diodes, and the like. Substrate prescriptions for improved microLED transfer yield described below may apply to non-coated, coated, or substrates patterned layers, e.g., patterned metallic layers and/or patterned semiconductor layers.

Intermediate carrier substrates for electronic device transfer, such as the transfer of microLEDs, are currently requested by industry with non-coated attributes of TTV less than 2 μm and warp less than 10 micrometers (μm). Similarly, Gen-size glass substrates for display backplane fabrication are currently requested with non-coated attributes for a 150 mm×150 mm moving window thickness variation less than 9 μm, full-sheet warp less than 500 μm, waviness less than 0.06 μm in a spatial wavelength range from 0.8 mm to 8 mm, and waviness less than 0.33 μM in a spatial wavelength range from 0.8 mm to 25 mm. These attributes of glass substrates and Gen-sized backplane glass substrates are specified for non-coated substrates and chosen for reasons other than electronic device transfer.

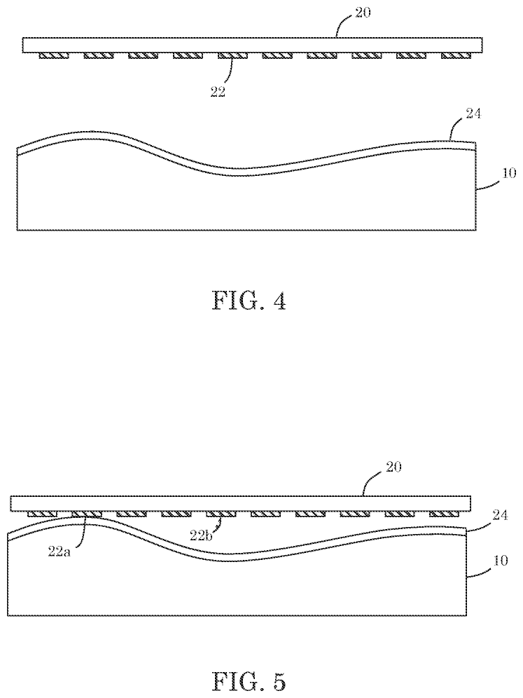

An improvement in transfer efficiency of electronic device transfer onto substrates was discovered using a combination of experimental measurement and simulation. Glass substrates samples were characterized using a Tropel® Flatmaster® Multi-Surface Profiler, which can provide a detailed topographical map of a surface. Surface topography mapping was used to characterize warp, total thickness variation (TTV), local thickness variation (LTV), waviness, etc., of each substrate sample. This detailed surface information was used to construct a simulation of a microLED stamp transfer process onto the surface of each substrate sample. A schematic of the simulation is shown in FIGS. 4 and 5, where a stamp 20 loaded with microLEDs on a surface thereof is lowered onto various locations on the substrate surface. If the microLEDs on the stamp contact an adhesion layer 24 disposed on the substrate surface, the microLEDs will be transferred to the substrate. However, some areas of the substrate may have high local surface variation (e.g., waviness) such that not all of the microLEDs can come in contact with the substrate. Thus, the simulation can predict the percentage of microLEDs that will be transferred to a given substrate based on the surface topography of that substrate along with other process variables such as the stamp size, applied pressure, and spacing of the microLEDs. The percentage of successful transfers compared to the total number of possible transfers (total number of microLEDs disposed on the stamp) indicates the transfer efficiency. That is, transfer efficiency is determined as (the number of successful microLED transfers during a transfer event/total number of microLEDs in the transfer event)×100%.

By simulating hundreds of stamp transfer processes on dozens of substrates, a representation of what surface features allow for effective microLED transfer and what features do not can be described. Using surface topography data such as warp, LTV, and waviness of the substrate region below the transfer stamp, transfer efficiency can be calculated. The data show no prediction of transfer efficiency can be made by characterizing warp or thickness variation alone, as commonly thought. Analysis shows warp is a poor metric because most of the warp in the substrate is eliminated by the chucking process, where the substrate is held to a surface with a vacuum (chucking) during the transfer process, and stamp bond force. Studies on substrate chucking show the smaller wavelength features of surface variations remain after chucking. Similarly, TTV is a poor predictor because it considers two points of the substrate surface, the point of greatest thickness and the point of least thickness. Local thickness variation (LTV) considers thickness variation over the area of the stamp, but LTV is still a poor predictor because it depends on characteristics of both the top and bottom surfaces of the substrate. On the other hand, waviness captures the quality of the substrate top surface while considering features over a spatial wavelength range relevant to the transfer of microLEDs. Thus, substrates (e.g., wafers) that optimize waviness over other factors can result in greater transfer success.

Analysis further showed the unique attribute for microLED transfer considerations is maximum waviness over a 50 mm×50 mm moving window in a spatial wavelength range of about 0.25 mm to about 50 mm, and more particularly from about 30 mm to about 50 mm. Secondary combinations of warp and LTV may also play a reduced role. Glass substrates can range in size from 100 mm×100 mm wafers to greater than 1×1 m² sheets. Elastic modulus values of the glass substrates can range from about 60 GigaPascals (GPs) to about 90 GPa when measured by resonant ultrasound spectrometry according to ASTM C623, “fest Method for Youngs Modulus, Shear Modulus, and Poissons Ratio for Glass and Glass-Ceramics by Resonance.” Thicknesses of the glass substrates can range from about 0.1 mm to about 1 mm, from about 0.1 mm to about 0.7 mm, from about 0.3 mm to about 1 mm, from about 0.1 mm to about 0.250 mm, from about 0.3 to about 1 mm, including all ranges and sub-ranges therebetween, where the thickness is defined as the distance between the first major surface of the substrate and the second major surface of the substrate along a line orthogonal to either one or both the first and second major surfaces. Coefficient of thermal expansion (CTE) values for the glass substrate can range from about 3 ppm/° C. to about 10 ppm/° C. over a temperature range from about 0° C. to about 300° C. when measured according to ASTM E228—17, “Standard Test Method for Linear Thermal Expansion of Solid Materials With a Push-Rod Dilatometer.”

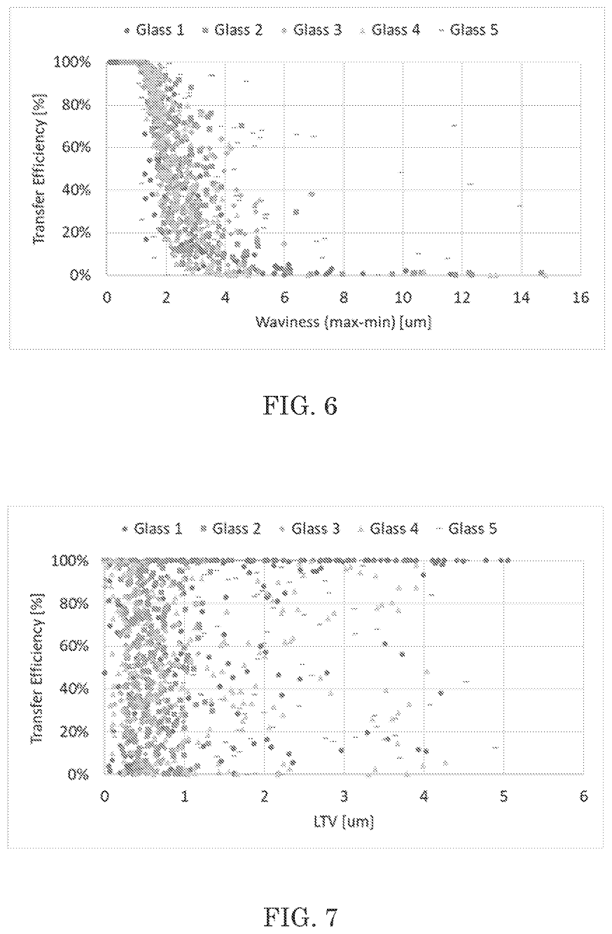

The following describes in more detail the experimental work undertaken to evaluate the effects of waviness on electronic component transfer efficiency. Twenty-three glass substrates were measured for topographical attributes (e.g., warp, LTV, and waviness) using a Tropel Flatmaster. The substrates were 200 mm diameter discs and comprised three different commercially available glasses: an alkaline earth aluminoborosilicate glass (Glass 1 and 3), two different alkali-free aluminoborosilicate glasses (Glass 2 and 4), and an alkali-free borosilicate glass (Glass 5). These data were then used to create digital facsimiles of glass wafers (virtual glass wafers) exhibiting various combinations of the measured attributes, and a plurality of simulations were performed wherein a hypothetical stamp comprising a plurality of microLEDs was used to digitally stamp the virtual glass wafers. The stamp was modeled with a stamp surface of 30 mm×30 mm. The stamp was considered rigid and flat, with an elastic modulus of 70 GPa. It was further assumed the force applied to the virtual glass wafers by the stamp was 1 Newton (N). The pixel pitch (spacing between microLED structures) was assumed to be 200 μm, and the thickness of an adhesive layer disposed on the virtual glass wafers was set at 1 μm. It was further assumed the adhesive layer was compliant and deformed as needed. Each microLED was assumed to be a square 15 μm×15 μm structure with a thickness of 5 μm. A microLED was considered to have successfully transferred to a virtual glass wafer if one half or greater of the contact surface (the surface facing the adhesive layer) of an individual microLED contacted the adhesive. Both bow and warp were considered to have been removed from the virtual glass wafers by vacuum chucking. The simulation data are shown in FIGS. 6, 7, and 8.

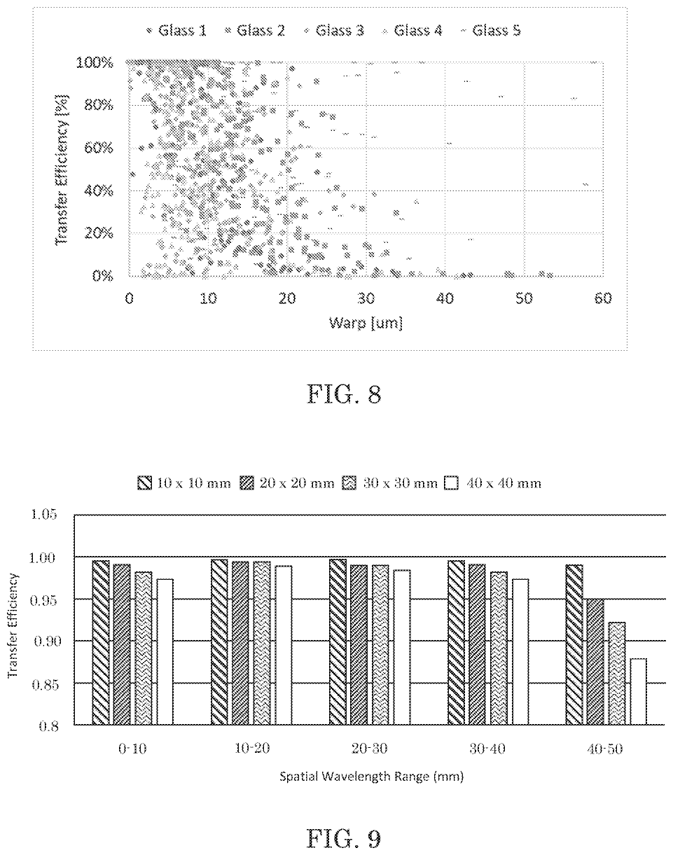

FIG. 6 depicts simulated microLED transfer efficiency in percent as a function of maximum waviness for a spatial wavelength in a range from 0.25 mm to 50 mm, expressed in μm. Features with a spatial wavelength less than 0.25 mm were considered surface roughness and features with a spatial wavelength greater than 50 mm were categorized as warp. In practice, the reported maximum waviness is the variation in surface height after the low and high spatial wavelength features have been digitally filtered from the surface data. FIG. 6 shows that, independent of the glass substrate composition or source, waviness of a specific spatial wavelength has a strong correlation to stamp transfer yield. The data show that using a glass substrate with a maximum waviness in a 50 mm×50 mm moving window equal to or less than about 1 μm, such as equal to or less than about 0.75 μm, or equal to or less than about 0.5 μm, for a spatial wavelength in a range from 0.25 mm to 50 mm, can produce a transfer efficiency of about 100%. On the other hand, little correlation is shown for LTV, or warp, as depicted in FIGS. 7 and 8, respectively.

FIG. 9 shows simulated transfer efficiency for glass wafers after all surface features were filtered from the data except for the specific spatial wavelength ranges indicated above (0.25 mm to 50 mm). Stamp size was varied to better understand how stamp size contributes to transfer efficiency. The data show transfer efficiency is consistently high for small, e.g., 10 mm×10 mm, stamp size, but decreases as stamp size increases. This is significant for processes scaling toward higher throughput manufacturing. Longer spatial wavelengths, particularly greater than 30 mm, are particularly poor for transfer with larger stamps. The smallest spatial wavelengths, for example in a range from about 0 mm to about 10 mm, also performed poorly for large stamps. The results show that, as manufacturers move to larger stamp sizes to increase efficiency, wafers may need to exhibit reduced waviness in the 30 mm to 50 mm spatial wavelength range to maintain acceptable transfer efficiency. Moreover, the results demonstrate the need to use wafers with not just low waviness, but low waviness in the about 0.25 mm to about 50 mm spatial wavelength range, and more particularly in the spatial wavelength range from about 30 mm to about 50 mm. This spatial wavelength range is not currently characterized in Gen-size, commercially available glass substrate products.

In limited situations, microLEDs can be transferred to bare, non-coated substrates. In most cases microLEDs will be transferred to a substrate that has undergone adhesive coating or electronic component fabrication processes. Considering this, substrate attributes with combined coatings and structures should be specified for efficient microLED transfer efficiency because the substrate three-dimensional shape may change after processing, e.g., after thermal cycling. This is especially true in the vertical z-direction that is overlooked in current x-y glass compaction studies. For example, significantly increased warp and waviness can be observed when thermal cycling aluminoborosilicate substrates to 500° C. and 650° C. conditions, conditions that could be experienced by the wafers during deposition of TFTs. Accordingly, while the glass wafer measurements performed in the present experiments were taken on bare glass samples, it was assumed these measurement results represented post-processing surface characteristics. That is, the bare samples were assumed to have been heat treated, such as during TFT deposition processes, that could alter surface topography.

While various embodiments have been described in detail relative to certain illustrative and specific examples thereof, the present disclosure should not be considered limited to such, as numerous modifications and combinations of the disclosed features are possible without departing from the scope of the following claim s.

What it claimed is:

1. A substrate, comprising:
a first major surface, a second major surface opposite the first major surface, and a thickness therebetween, wherein a maximum waviness of the substrate evaluated over a 50 mm×50 mm area of the first major surface or the second major surface comprises a magnitude less than or equal to about 1 μm in a spatial wavelength range from about 0.25 mm to about 50 mm.

2. The substrate of claim 1, the substrate further comprising an electrically functional layer disposed on the first major surface.

3. The substrate of claim 2, wherein the electrically functional layer comprises a plurality of metallic conductors.

4. The substrate of claim 2, wherein the electrically functional layer comprises a thin film transistor.

5. The substrate of claim 1, wherein the spatial wavelength is in a range from about 30 mm to about 50 mm.

6. The substrate of claim 1, wherein the waviness is equal to or less than about 0.5 μm.

7. The substrate of claim 1, further comprising an adhesive layer disposed on the first major surface.

8. The substrate of claim 1, wherein a surface area of the first major surface is equal to or greater than 1×10⁴ mm².

9. The substrate of claim 1, wherein a surface area of the first major surface is equal to or greater than about 1 m².

10. The substrate of claim 1, wherein a thickness of the substrate is in a range from about 0.1 mm to about 1 mm.

11. The substrate of claim 1, wherein a coefficient of thermal expansion of the glass substrate is in a range from about 3 ppm/° C. to about 10 ppm/° C. over a temperature range from 0° C. to 300° C.

12. The substrate of claim 1, wherein the substrate is a silica-based glass substrate.

13. The substrate of claim 1, wherein the maximum waviness is evaluated over a 30 mm×30 mm area.
